(19) United States
(12) Patent Application Publication
(10) Pub. No.: US 2007/0063752 A1
(43) Pub. Date: Mar. 22, 2007

(54) MASTER-SLAVE FLIP FLOP

(75) Inventors: Gregor Kowalczyk, Gratkorn (AT); Holger Bock, Graz (AT); Josef Haid, Graz (AT)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Munich (DE)

(21) Appl. No.: 11/532,584

(22) Filed: Sep. 18, 2006

(30) Foreign Application Priority Data
Sep. 16, 2005 (DE) 10 2005 044 333.8

(51) Int. Cl. H03K 3/289

(52) U.S. Cl. 327/202

(57) ABSTRACT

Master-slave flip flop including a master latch having a data input for receiving a data input signal, an inverting clock input for receiving a first clock signal, and a data output, a slave latch having a data input which is connected to the data output of the master latch, a clock input for receiving a second clock signal, and a data output for outputting an output signal, and a time delay element connects the clock input of the slave latch to the clock input of the master latch.

### CROSS-REFERENCE TO RELATED APPLICATION

This application claims priority to German Patent Application Serial No. 10 2005 044 333.8, which was filed on Sep. 16, 2005, and is incorporated herein by reference in its entirety.

1. Field of the Invention

The invention relates to a master-slave flip flop having a master latch with a data input for receiving a data input signal, an inverting clock input for receiving a first clock signal, and a data output, and having a slave latch with a data input which is connected to the data output of the master latch, a clock input for receiving a second clock signal and a data output for outputting an output signal, particularly to a master-slave flip flop for use in synchronous circuits.

2. Background of the Invention

Synchronous circuits are characterized by a common clock signal which is applied to the clock inputs of the components of the circuit. If the components are flip flops, the levels at their outputs change close to the active clock edges in time. In the worst case, all levels change simultaneously at all outputs of the flip flops and large dynamic currents flow. These current peaks can lead to instabilities in the supply voltage and to crosstalk between adjacent conductor tracks, and to increased EMC radiation. In contactless chip cards in which communication takes place by means of load modulation of the carrier signal, such fluctuations in the current consumption can lead to unwanted modulations which are falsely interpreted as information by the reading device. The abovementioned problems occur, in particular, in circuit components which must drive a large load such as, for example, in the case of bus drivers which are implemented by means of flip flops. In the case of a 32-bit wide system bus, the levels of 32 flip flops can change simultaneously. Each flip flop must then recharge the capacitance of one data line.

A solution to the problems described above consists in using weaker bus drivers with lower dynamic current consumption. When a circuit is designed, the drivers are initially selected in such a manner that the time requirements set for the signal variations are met. If it is found during the circuit analysis that one of the data paths transmits the signal in a shorter time, the driver can be replaced by a weaker driver for this data path.

The disadvantageous factor when using weaker drivers is, however, that the signals then have a lesser steepness at the edges which can lead to an increase in the short-circuit current in the components connected to the drivers. If the edges are very flat, both transistors, for example in inverters, simultaneously conduct for a short time and the supply potential VDD is connected to the ground potential GND. The resultant short-circuit current leads to an increase in energy consumption which is unwanted, especially in the case of battery-operated applications.

A further disadvantage which occurs when using weaker drivers is that replacing a driver by a weaker driver can only be carried out at the end of the design of the circuit, that is to say after routing and layout. This is because it is only then that the accurate values for the temporal behaviour of the signals is available. If a weaker flip flop is used, simulation and verification must be repeated to see that no critical path is produced, as a result. This procedure can therefore only be automated to a limited extent and is laborious.

From WO 03/071681 A1, a circuit with two latches is known in which the data output of the first latch is connected to the data input of the second latch. The latches are clocked by two separate signals which do not overlap in time. Since the latches thus change their levels at different times, the current required for recharging can be distributed in time. The disadvantageous factor in this solution is, however, that two non-overlapping clock signals must be provided. On the one hand, this is costly since the additional clock signal must be generated and must be taken into consideration during the simulation and in the layout. On the other hand, the demand that the clock signals must not overlap leads to the maximum possible clock frequency being limited and the forms of clock signal suitable for operation being restricted.

### SUMMARY OF THE INVENTION

A master-slave flip flop including a master latch, a slave latch, and a time delay element. The master latch has a data input for receiving a data input signal, an inverting clock input for receiving a first clock signal, and a data output. The slave latch has a data input, which is connected to the data output of the master latch, a clock input for receiving a second clock signal, and a data output for outputting an output signal. The time delay element connects the clock input of the slave latch to the clock input of the master latch.

### BRIEF DESCRIPTION OF THE DRAWINGS

In the text which follows, the invention will be explained in greater detail on an illustrative embodiment, referring to the drawings, in which:

FIG. 1 shows an illustrative embodiment of a master-slave flip flop with a time delay element;

FIG. 2 shows illustrative variations of signals of the master-slave flip flop shown in FIG. 1;

FIG. 3 shows an illustrative embodiment of a time delay element with adjustable time delay;

FIG. 4 shows the use of master-slave flip flops from FIG. 1 in a synchronous bus; and

FIG. 5 shows illustrative variations of signals of the flip flops shown in FIG. 4.

### DETAILED DESCRIPTION OF THE PREFERRED EMBODIMENTS

The present invention reduces the dynamic current which occurs close to the active clock edges in time with a simultaneous change in the levels of flip flops in synchronous circuits. In addition, a corresponding method is specified.

A master-slave flip flop is provided which includes a master latch with a data input for receiving a data signal, with an inverting clock input for receiving a first clock signal and with a data output, and a slave latch with a data input which is connected to the data output of the master latch, with a clock input for receiving a second clock signal and with a data output for outputting an output signal. The clock input of the slave latch is connected to the clock input of the master latch via a time delay element. Due to the time delay element, the output signal of the slave latch appears delayed in time with respect to the first clock signal. In this manner, the switching time of the output signal of the slave latch can be delayed.

According to an advantageous embodiment, the time delay element has an adjustable time delay. The time delay can thus be adapted to various parameters such as, for example, to the number of flip flops, to the clock signal frequency or to the available times in data paths which are not time-critical.

According to an advantageous embodiment, the time delay element has a plurality of delay paths having different delay times, wherein one of the delay paths can be selected by a control signal. In this manner, master-slave flip flops with different delay times between the clock signal at the clock input of the master latch and the output signal at the data output of the slave latch can be implemented by a single master-slave flip flop and circuits having a plurality of such master-slave flip flops can be simulated in a simple manner.

According to an advantageous embodiment, the selection of one of the delay paths is effected by a multiplexer. By applying a control signal, one of the plurality of delay paths can be selected by means of the multiplexer and thus the delay time between the clock signal at the clock input of the master latch and the output signal at the data output of the slave latch can be adjusted.

According to an advantageous embodiment, the delay paths have a different number of series-connected non-inverting buffers. Buffers can be implemented, for example, by cascading two inverters and have a fixed delay time. The delay time can be arbitrarily increased by connecting the buffers in series.

According to an advantageous embodiment, the master latch and the slave latch are D-type latches. D-type latches are clock-state-controlled storage elements which are available in any standard cell library.

According to an advantageous embodiment the clock signal at the clock input of the slave latch and the clock signal at the clock input of the master latch overlap in time. In this manner, the master-slave flip flop can be operated at a higher clock frequency than when the clock signals of the slave latch and of the master latch are not allowed to overlap in time.

According to an advantageous embodiment, the time delay element has a time delay which, on the one hand, is longer than the time delay between the application of a clock signal edge at the clock input of the master latch and the presence of an output signal at the data output of the slave latch in the case of a master-slave flip flop without time delay element, and, on the other hand, shorter than the period of the applied clock signal minus the set-up time of a subsequent clock-controlled component. The time delay of the time delay element must not be too great since otherwise the set-up times of subsequent clock-controlled components are violated. In actual circuit arrangements, combinatorial gates such as, for example, inverters can be arranged between a flip flop according to the invention and a subsequent clock-controlled component. In this case of indirectly following clock-controlled components, the time delay must be shorter than the period of the applied clock signal minus the delay in the combinatorial path and minus the set-up time of the indirectly following clock-controlled component.

According to an advantageous embodiment, the time delay of the time delay element depends on the first clock signal. In this manner, the time delay can be correspondingly adapted, e.g. to the frequency of the clock signal. In the case of a clock signal having a higher frequency, shorter time delays are required than in the case of a clock signal having a lower frequency. At the same time, it is possible, due to the coupling of the time delay to the frequency of the clock signal, to prevent the time delay being longer than half a clock period of the clock signal and thus the operation of the master-slave flip flop or, respectively, the synchronism of the circuit in which the master-slave flip flop is used being jeopardized. As an alternative or additionally, the signal form of the clock signal such as, e.g., its duty ratio or the steepness of its edges can be taken into consideration in the choice of time delay.

According to an advantageous embodiment, the set-up and hold time of the master-slave flip flop corresponds to the set-up and hold time of a master-slave flip flop without time delay element. If the master-slave flip flop according to the invention is considered as a black box, it has the same characteristic as standard flip flops. Circuits built up with the flip flops according to the invention can therefore be used, simulated and analysed with the same methods as are used for standard flip flops and are thus suitable for automated design flow.

A bus driver for driving parallel data lines having a plurality of master-slave flip flops is also provided.

According to an advantageous embodiment, at least one of the master-slave flip flops has a time delay between the clock input of the master latch and the clock input of the slave latch which differs from the time delays between the clock inputs of the slave latches and the clock inputs of the master latches of the other master-slave flip flops.

According to an advantageous embodiment, the time delay elements between the clock inputs of the slave latches and the clock inputs of the master latches have time delays which differ from one another. Due to the different time delay, the switching times of the signals at the outputs of the master-slave flip flops can be distributed in time so that when the levels change, the currents are no longer superimposed and thus the current peaks are reduced.

Also provided is a method for reducing current peaks when the states of master-slave flip flops in synchronous networks change, wherein the clock of the slave latch is delayed in time with respect to the clock of the master latch in at least one of the master-slave flip flops. Due to the time delay, the switching time of the signals at the outputs of the master-slave flip flops, and thus also the associated current flow, shifts with respect to the clock so that the current flow can be distributed in time and the current peaks are reduced.

According to an advantageous embodiment, the time delay of the clock of the slave latch differs from the clock of the master latch of jointly triggered master-slave flip flops in the individual master-slave flip flops.

FIG. 1 shows an illustrative embodiment of the master-slave flip flop FF according to the invention, which consists of a master latch M, a slave latch S and a time delay element ZE. The data input EM of the master latch M forms the data input of the master-slave flip flop and is used for receiving a data signal D. A first clock CLK is applied to the inverting clock input CM of the master latch M. The data output AM of the master latch is used for outputting the signal QM and is connected to the data input ES of the slave latch S. The clock input CS of the slave latch S is used for receiving a second clock signal CLKS and is connected to the clock input CM of the master latch M via the time delay element ZE. The time delay element ZE optionally has an input for a control signal SD by means of which the delay time DT between the input and the output of the time delay element ZE can be adjusted. The data output AS of the slave latch S forms the output of the master-slave flip flop FF and is used for outputting an output signal Q. The master latch M and the slave latch S are constructed as D-type flip flops.

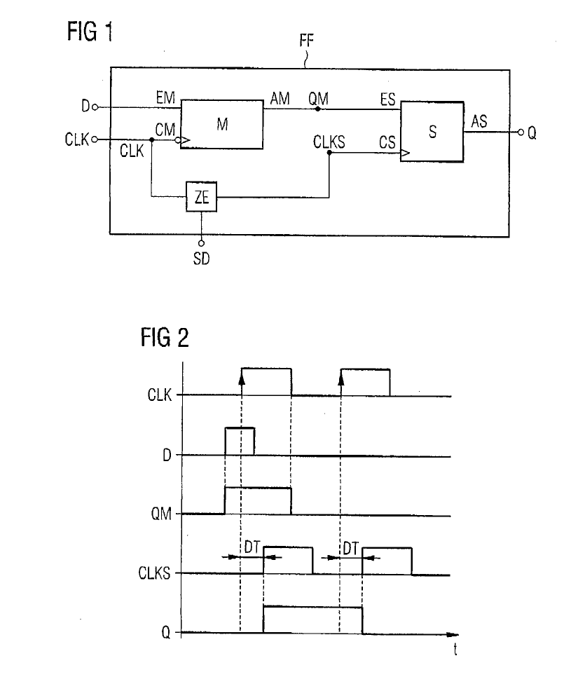

FIG. 2 shows illustrative signal variations of the first clock signal CLK, of the data signal D, of the output signal QM of the master latch, of the second clock signal CLKS and of the output signal Q of the master-slave flip flop FF. If the first clock signal CLK is at a Low level, the master latch M, due to the inverting at the clock input CM of the master latch, is switched in such a manner that the output signal QM of the master latch follows the data signal D which is present at the data input EM of the master latch M. If the clock signal CLK assumes a High level, the currently existing level is stored in the master latch M.

The clock signal CLKS of the slave latch is delayed by the time DT with respect to the clock signal CLK of the master. If the clock signal CLKS of the slave latch is at a Low level, the currently existing level is stored in the slave latch S. If the clock signal CLKS of the slave has a High level, the output signal Q at the data output AS of the slave latch follows the output signal QM of the master latch that is present at the data input ES of the slave latch. Thus, the level change of the output signal Q is delayed by the time DT with respect to the rising clock pulse edge of the clock signal CLK. If the clock signal CLK of the master latch drops to a Low level, the output signal QM at the output AM of the master latch again follows the data signal D present at the data input EM of the master latch. With the second rising edge of the clock signal CLK of the slave, the new level of the output signal QM of the master latch, which is a Low level, is accepted and stored by the slave.

In the illustrative embodiment shown in FIG. 1, the first clock CLK is supplied to an inverting clock input CM of the master latch and the second clock CLKS is supplied to a non-inverting clock input CS of the slave latch. As an alternative, the clock input CS of the slave latch can be inverting and the clock input CM of the master latch can be non-inverting. The master-slave flip flop shown in FIG. 1 has the same set-up and hold times as standard flip flops so that it can be treated like a standard cell in the circuit synthesis.

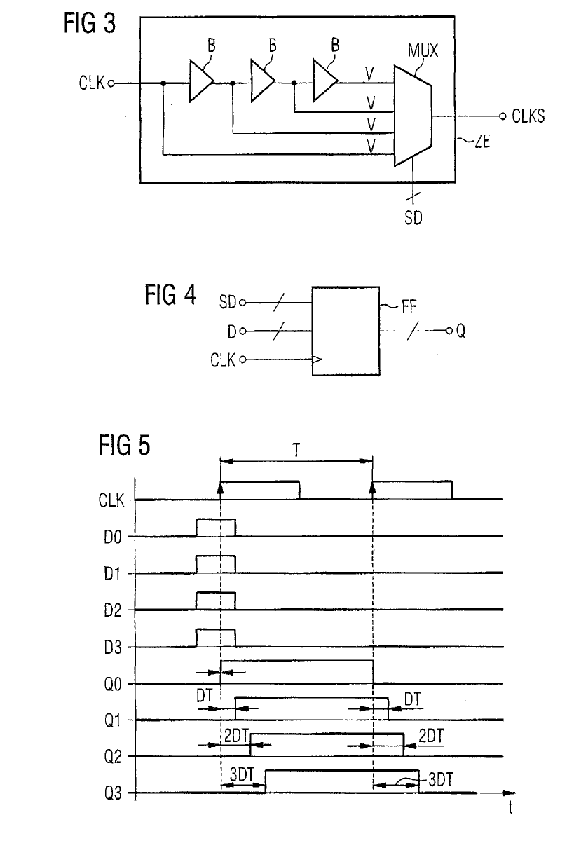

FIG. 3 shows an illustrative embodiment of a time delay element ZE in which the time delay DT is adjustable. The time delay DT of the output signal CLKS with respect to the input signal CLK can be adjusted by applying a control signal SD. The time delay element ZE consists of a series circuit of three non-inverting buffers B and of a multiplexer MUX. The multiplexer MUX is supplied with four input signals: the undelayed clock signal CLK, the clock signal CLK delayed by a buffer B, the clock signal CLK delayed by two buffers B and the clock signal CLK delayed by three buffers B. If the buffers B in each case have a time delay of DT, the signals present at the multiplexer MUX have the delays 0, DT, 2*DT and 3*DT with respect to the clock signal CLK. By applying a control signal SD, one of the delay paths V is selected and one of the four signals is forwarded to the output of the multiplexer MUX.

The time delay element ZE with adjustable time delay can be implemented in many ways. Instead of a multiplexer, the buffers B could be bypassed, for example, by one switch each. If these switches are appropriately driven, different time delays can be achieved. In a further variant, frequency-dependent time delay elements could be used instead of the buffers B so that the desired delay is automatically adapted to the frequency of the first clock signal CLK and does not exceed a maximum value which is given, for example, by half the period of the clock signal CLK.

FIG. 4 shows the use of a plurality of the master-slave flip flops according to the invention for driving data lines in a synchronous parallel data bus. The master-slave flip flops FF are combined in an array, using one flip flop FF for each data line. The plurality of master-slave flip flops FF, for example four, is clocked by a common clock signal CLK. The data to be transmitted are present in parallel at the data inputs D. The parallel outputs Q are connected to the data lines to be driven. The delay time DT between the active clock pulse edge of the clock signal CLK and the presence of the data at the outputs Q can be adjusted individually for each of the master-slave flip flops FF via the control inputs SD. In order to reduce the current peaks occurring in the case of simultaneous level changes of the signals at the outputs Q, the time delay DT of at least one of the master-slave flip flops FF is selected via the control signal SD in such a manner that it differs from the time delay DT of the other master-slave flip flops FF. In the case of a plurality of master-slave flip flops FF, the switching current can be distributed over half a period of the clock signal CLK by means of different time delays DT of the individual flip flops FF.

FIG. 5 shows illustrative signal variations of the clock signal CLK, of the data signals D0 to D3 and of the output signals Q0 to Q3 of the master-slave flip flops FF shown in FIG. 4. The control signals SD of the individual master-slave flip flops FF are set in such a manner that there is no time delay at the first master-slave flip flop FF, a time delay of DT at the second one, a time delay of 2*DT at the third one and a time delay of 3*DT at the fourth one. To illustrate the timing relationships, signals having the same levels are in each case applied to the data inputs D0 to D3 of the master-slave flip flop FF. With a rising clock pulse edge of the clock signal CLK, the level present at the data inputs is transferred and output with the selected time delay at the output Q and stored. With the next rising clock signal edge CLK, the new data DO to D3 are transferred and output at the output Q with the time delay set. Since the signals at the outputs Q0 to Q3 in each case switch at different times, the current required for this is distributed over these times and there is no superposition of the recharging currents of the individual flip flops FF. Reducing the current peaks relieves the voltage supply at the active clock pulse edges of the clock signal CLK, reduces crosstalk, improves electromagnetic compatibility and thus achieves the object forming the basis for the invention.

The use of the master-slave flip flops FF shown in FIG. 4 is particularly advantageous for driving bus lines in synchronous buses such as, for example, the Advanced Microcontroller Bus Architecture (AMBA) since relatively large capacitances must be recharged in this case. The standard flip flops can be replaced here by the flip flops proposed according to the invention. Since the master-slave flip flops can also be fully characterized, the standard flip flops can be simply replaced by these during the circuit synthesis and the design flow can be performed without any type of manual processing.

What is claimed is:

1. A master-slave flip flop comprising:
a master latch having a data input for receiving a data input signal, an inverting clock input for receiving a first clock signal, and a data output;
a slave latch having a data input which is connected to the data output of the master latch, a clock input for receiving a second clock signal, and a data output for outputting an output signal; and
a time delay element connecting the clock input of the slave latch to the clock input of the master latch.

2. The master-slave flip flop according to claim 1, wherein the time delay element has an adjustable time delay.

3. The master-slave flip flop according to claim 2, wherein the time delay element has a plurality of delay paths with different respective delay times, and one of the delay paths can be selected by a control signal.

4. The master-slave flip flop according to claim 3, wherein the selected delay path is selected by a multiplexer.

5. The master-slave flip flop according to claim 3, wherein each of the delay paths has a different number of series-connected non-inverting buffers.

6. The master-slave flip flop according to claim 1, wherein the master latch and the slave latch are D-type latches.

7. The master-slave flip flop according to claim 6, wherein the clock signal at the clock input of the slave latch overlaps the clock signal at the clock input of the master latch in time.

8. The master-slave flip flop according to claim 1, wherein the time delay element has a time delay which
is longer than a time delay between the application of a clock signal edge at the clock input of the master latch and the presence of an output signal at the data output of the slave latch in a case of an otherwise corresponding master-slave flip flop without a time delay element, and
is shorter than a period of an applied clock signal.

9. The master-slave flip flop according to claim 1, wherein a time delay of the time delay element depends on the first clock signal.

10. The master-slave flip flop according to claim 1, wherein the set-up and hold time of the master-slave flip flop corresponds to the set-up and hold time of a master-slave flip flop without a time delay element.

11. A bus driver for driving parallel data lines having a plurality of master-slave flip flops according to claim 1.

12. The bus driver according to claim 11, wherein at least one master-slave flip flop has between the clock input of the slave latch and the clock input of the master latch a time delay which differs from the time delays between the clock inputs of the slave latches and the clock inputs of the master latches of the other master-slave flip flops.

13. The bus driver according to claim 12, wherein the time delay elements between the clock inputs of the slave latches and the clock inputs of the master latches have time delays which differ from one another.

14. A method for reducing current peaks during changing of states of master-slave flip flops in synchronous networks comprising the step of delaying a clock signal of the slave latch in time with respect to a clock signal of the master latch in at least one of the flip flops.

15. The method according to claim 14, wherein the time delay is adjustable.

16. The method according to claim 15, wherein the time delay is dependent on the clock signal of the master latch.

17. The method according to claim 15, wherein the time delay between the clock signal of the slave latch and the clock signal of the master latch of jointly triggered master-slave flip flops is different in the individual master-slave flip flops.

18. The method according to claim 17, wherein the time delay between the clock signal of the slave latch and the clock signal of the master latch
is longer than a time delay between the application of a clock signal edge at a clock input of the master latch and the presence of an output signal at a data output of the slave latch in an otherwise corresponding master-slave flip flop without a time delay between the clock signals of the slave latch and the master latch, and
is shorter than a period of an applied clock signal.

19. A master-slave flip flop comprising:
a master latch having a data input for receiving a data input signal, an inverting clock input for receiving a first clock signal, and a data output;
a slave latch having a data input which is connected to the data output of the master latch, a clock input for receiving a second clock signal, and a data output for outputting an output signal; and
a time delay means, which connects the clock input of the slave latch to the clock input of the master latch, for delaying the first clock signal to produce the second clock signal.

20. A synchronous network comprising:
a plurality of master-slave flip flops; and
a time delay element configured to delay a clock signal of the slave latch in time with respect to a clock signal of the master latch in at least one of the flip flops to thereby reduce current peaks during changing of states of the plurality of master-slave flip flops.

21. The synchronous network according to claim 20, wherein the time delay element has an adjustable time delay.

22. The synchronous network according to claim 21, wherein the time delay element has a plurality of delay paths with different respective delay times, and one of the delay paths can be selected by a control signal.

23. The synchronous network according to claim 22, wherein the selected delay path is selected by a multiplexer.

24. The synchronous network according to claim 3, wherein each of the delay paths has a different number of series-connected non-inverting buffers.
